(19) United States
(12) Patent Application Publication
(10) Pub. No.: US 2024/0339431 A1
(43) Pub. Date: Oct. 10, 2024

(54) BONDING METHOD AND BONDING SYSTEM

(71) Applicant: Tokyo Electron Limited, Tokyo (JP)

(72) Inventors: Kazutaka Noda, Koshi City (JP); Atsushi Nagata, Koshi City (JP); Takashi Terada, Koshi City (JP)

(21) Appl. No.: 18/625,419

(22) Filed: Apr. 3, 2024

(30) Foreign Application Priority Data
Apr. 5, 2023 (JP) 2023-061426

(51) Int. Cl. H01L 23/00

(52) U.S. Cl. CPC H01L 24/80; H01L 24/05; H01L 24/74; H01L 2224/05647; H01L 2224/74; H01L 2224/80009; H01L 2224/80895; H01L 2224/80896

(57) ABSTRACT

A bonding method of bonding substrates, a metal material being exposed on each of the substrates, is provided. The bonding method includes modifying a surface of each of the substrates to be bonded with a plasma of a processing gas; hydrophilizing the modified surface of each of the substrates; and bonding the hydrophilized surfaces of the substrates. In the hydrophilizing of the modified surface, a processing liquid is supplied to the surface of each of the substrates, and a recess amount of the metal material is controlled with the processing liquid.

### CROSS-REFERENCE TO RELATED APPLICATION

This application claims the benefit of Japanese Patent Application No. 2023-061426 filed on Apr. 5, 2023, the entire disclosure of which is incorporated herein by reference.

### TECHNICAL FIELD

The exemplary embodiments described herein pertain generally to a bonding method and a bonding system.

### BACKGROUND

Patent Document 1 discloses a bonding system that bonds substrates by an intermolecular force. This bonding system includes a surface modifying apparatus configured to modify surfaces of the substrates, a hydrophilizing apparatus configured to hydrophilize the modified surfaces of the substrates, and a bonding apparatus configured to bond the hydrophilized substrates to each other.
Patent Document 1: Japanese Patent Laid-open Publication No. 2017-073455

### SUMMARY

In one exemplary embodiment, a bonding method of bonding substrates, a metal material being exposed on each of the substrates, is provided. The bonding method includes modifying a surface of each of the substrates to be bonded with a plasma of a processing gas; hydrophilizing the modified surface of each of the substrates; and bonding the hydrophilized surfaces of the substrates. In the hydrophilizing of the modified surface, a processing liquid is supplied to the surface of each of the substrates, and a recess amount of the metal material is controlled with the processing liquid.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

In the detailed description that follows, exemplary embodiments are described as illustrations only since various changes and modifications will become apparent to those skilled in the art from the following detailed description. The use of the same reference numerals in different figures indicates similar or identical items.

FIG. 1 is an explanatory diagram illustrating a recess formed in a surface of a wafer by a recess processing;

FIG. 2 is a schematic plan view illustrating a configuration of a bonding system according to a present exemplary embodiment;

FIG. 3 is a schematic side view illustrating configurations of an upper wafer and a lower wafer;

FIG. 4 is a schematic cross-sectional view illustrating a configuration of a surface modifying apparatus;

FIG. 5 is a schematic cross-sectional view illustrating a configuration of a surface hydrophilizing apparatus;

FIG. 6 is a schematic cross-sectional view illustrating a configuration of a bonding apparatus;

FIG. 7 is an explanatory diagram illustrating main processes of a wafer processing;

FIG. 8A is an explanatory diagram illustrating a state of a surface modifying processing and FIG. 8B is an explanatory diagram illustrating a state of a surface hydrophilizing processing; and

FIG. 9 is a Pourbaix diagram of copper serving as a metal wiring.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other exemplary embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

In a three-dimensional integration technique for stacking semiconductor devices three-dimensionally, bonding of two sheets of semiconductor wafers (hereinafter, simply referred to as “wafers”) on which an insulating film and a metal wiring are exposed is performed. The wafer is an example of a substrate. In the bonding system configured to perform a bonding processing, a surface modifying processing and a surface hydrophilizing processing are sequentially performed on surfaces of the wafers to be bonded to each other. Then, the wafers are bonded to each other by, for example, a Van der Waals force and hydrogen bonding (intermolecular force). Also, the bonding system disclosed in Patent Document 1 is equipped with various processing apparatuses configured to perform the surface modifying processing, the surface hydrophilizing processing and the bonding processing, respectively.

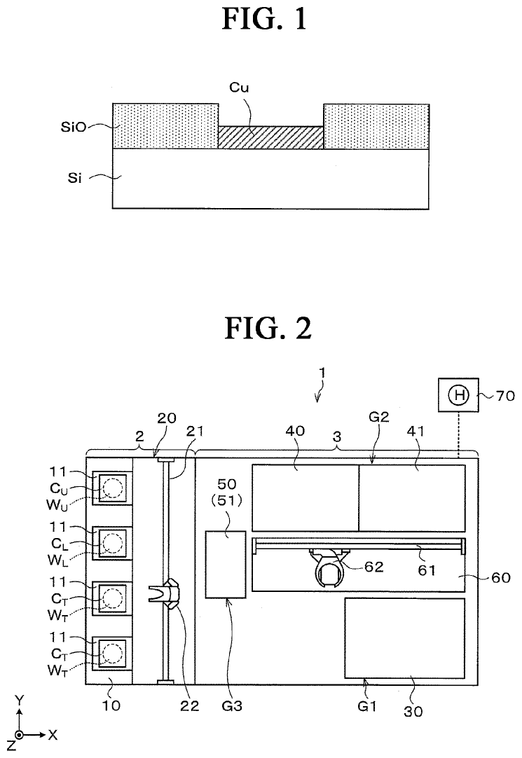

A combined wafer formed by bonding the wafers as described above is heated (annealed) to increase a bonding strength between the wafers. In this heating processing, the metal wiring exposed on the surface of the wafer thermally expands. Thus, to suppress damage to the metal wiring caused by the expansion, a height of a surface of the metal wiring (Cu in the illustrated example) formed on the surface of the wafer (Si in the illustrated example) is set to be lowered (or recessed) in advance compared to a height of a surface of the insulating film (SiO in the illustrated example), as shown in FIG. 1.

However, the recess processing is previously performed outside the bonding system. Therefore, for example, in the bonding system disclosed in Patent Document 1, even when a recess amount is insufficient or a recess amount is not uniform in the plane of the wafer, it cannot be adjusted prior to the bonding. Accordingly, the conventional bonding system needs to be improved.

The technique according to the present disclosure can improve the bonding quality of substrates bonded to form a combined substrate. Hereinafter, a bonding method according to the present exemplary embodiment and a bonding system configured to perform the bonding method will be described with reference to the accompanying drawings. Note that in the present specification and the drawings, same or corresponding parts will be assigned same reference numerals, and redundant description may be omitted.

### <Configuration of Bonding System>

First, a configuration of a bonding system according to the present exemplary embodiment will be described. FIG. 2 is a schematic plan view illustrating a configuration of a bonding system 1 according to the present exemplary embodiment. Further, in the following, to clarify positional relationships, the X-axis, Y-axis and Z-axis which are orthogonal to each other will be defined. The positive Z-axis direction will be regarded as a vertically upward direction.

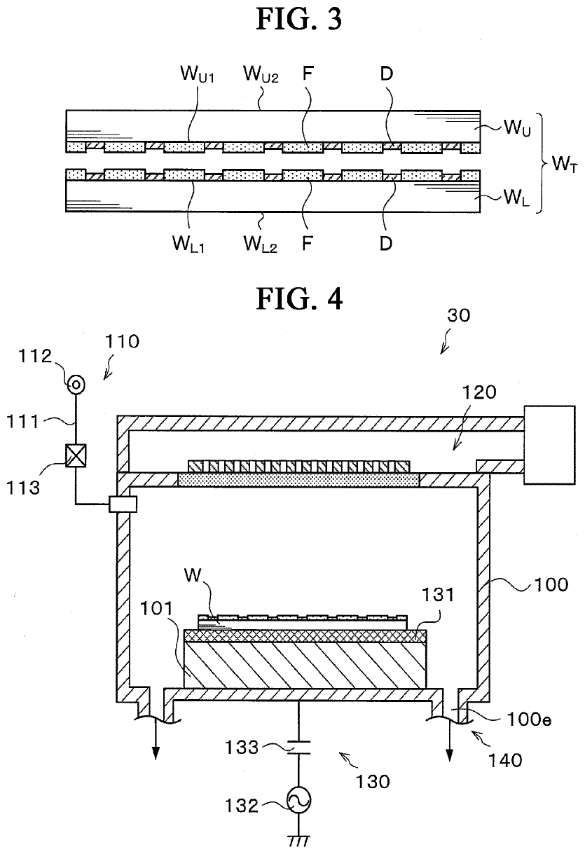

In the bonding system 1, wafers W as substrates are bonded to each other as shown in FIG. 3. Hereinafter, a wafer arranged at the upper side of a bonding apparatus to be described later is referred to as an “upper wafer W_{U}”, and a wafer arranged at the lower side is referred to as a “lower wafer W_{L}”. Further, a surface of the upper wafer W_{U} to be bonded to the lower wafer W_{L} is referred to as a “front surface W_{U1}”, and a surface opposite to the front surface W_{U1} is referred to as a “rear surface W_{U2}”. Similarly, a surface of the lower wafer W_{L} to be bonded to the upper wafer W_{U} is referred to as a “front surface W_{L1}” and a surface opposite to the front surface W_{U1} is referred to as a “rear surface W_{L2}”. In the following, the front surface W_{U1} of the upper wafer W_{U} and the front surface W_{U} of the lower wafer W_{U} may also be referred to as “front surface W₁”. Similarly, the rear surface W_{U2} of the upper wafer W_{U} and the rear surface W_{L2} of the lower wafer W_{L} may also be referred to as “rear surface W₂”. In the bonding system 1, the front surface W₁ of the upper wafer W_{U} and the front surface W₁ of the lower wafer W_{L} are bonded to each other to form a combined wafer W_{T} as a combined substrate.

The wafer W is a semiconductor wafer such as silicon wafer, and an insulating film F and a metal wiring D as a metal material are exposed on the front surface W₁. For example, a silicon oxide film (an SiO₂ film or an SiO film) may be used as the insulating film F. Also, for example, copper (Cu) or cobalt (Co) may be used as the metal wiring D. Further, a recess processing is performed in advance on the front surface W₁ of the wafer W carried into the bonding system 1 so that a height of a surface of the metal wiring D is lowered with respect to a height of a surface of the insulating film F. In an example, the recess processing is controlled by performing a chemical mechanical polishing processing (so-called “CMP processing”) on the wafer W. A depth (a recess amount) of the recess formed by the recess processing is, for example, less than 5 nm.

As shown in FIG. 2, the bonding system 1 has a configuration in which a carry-in/out station 2 and a processing station 3 are connected as one body. Cassettes C_{U}, C_{L} and C_{T} each of which can accommodate a plurality of upper wafers W_{U}, lower wafers W_{L} or combined wafers W_{T} are carried into and carried out of the carry-in/out station 2 with respect to, for example, the outside. The processing station 3 is equipped with various processing apparatuses configured to perform desired processings on the upper wafers W_{U}, the lower wafers W_{L} or the combined wafers W_{T}.

The carry-in/out station 2 is provided with a cassette placing table 10 on which the cassettes Cu, C_{L} and C_{T} are placed. Further, a wafer transfer section 20 is provided adjacent to the cassette placing table 10 in the positive X-axis direction of the cassette placing table 10. The wafer transfer section 20 is equipped with a wafer transfer device 22 configured to be movable on a transfer path 21 elongated in the Y-axis direction and configured to transfer the upper wafers W_{U}, the lower wafers W_{L} or the combined wafers W_{T} between the cassettes C_{U}, C_{L} and C_{T} on the cassette placing table 10 and transition devices 50 and 51 to be described later.

The processing station 3 is equipped with a plurality of, for example, three, processing blocks G1, G2 and G3 including various apparatuses. A surface modifying apparatus 30 configured to modify the front surface W₁ of the wafer W is provided in a first processing block G1. A surface hydrophilizing apparatus 40 configured to hydrophilize and clean the front surface W₁ of the wafer W and a bonding apparatus 41 configured to bond the upper wafer W_{U} and the lower wafer W_{L} are provided in a second processing block G2. Further, the transition devices 50 and 51 configured to temporarily hold the upper wafers W_{U}, the lower wafers W_{L} or the combined wafers W_{T} are provided in a third processing block G3.

In the surface modifying apparatus 30, for example, an oxygen gas or a nitrogen gas as a processing gas is excited and formed into a plasma to be ionized in a decompressed atmosphere. The oxygen ions or nitrogen ions are radiated onto the front surface W₁ of the wafer W, and, thus, the front surface W₁ is plasma-processed to be modified.

As shown in FIG. 4, the surface modifying apparatus 30 includes a processing container 100, a processing gas supply 110, a plasma generator 120, an ion attraction device 130, and an exhaust device 140.

The processing container 100 has a hermetically sealable inside. A non-illustrated carry-in/out opening for the wafer W is formed at the processing container 100, and the carry-in/out opening is provided with a non-illustrated gate valve. A stage 101 configured to attract and hold the rear surface W₂ of the wafer W is placed at a bottom portion of the processing container 100 so that the front surface W₁ of the wafer W faces upwards. For example, at least a part of the stage 101 is formed of an insulating member.

The processing gas supply 110 is configured to supply a processing gas into the processing container 100. The processing gas supply 110 includes a gas supply path 111, at least one gas source 112 and at least one flow rate controller 113 configured to introduce the processing gas into the processing container 100. The gas supply path 111 is configured to introduce the processing gas supplied from the gas source 112 into the processing container 100. The flow rate controller 113 may include, for example, a mass flow controller or a pressure control type or a flow rate modulation device. Also, the processing gas supplied from the gas source 112 is not limited to the oxygen gas or the nitrogen gas. For example, an argon gas or a helium gas may be supplied.

The plasma generator 120 is configured to generate plasma of the processing gas inside the processing container 100. In the illustrated example, the plasma generator 120 is equipped with a surface wave plasma (SWP) generating apparatus. However, the configuration of the plasma generator 120 is not particularly limited, and the plasma generator 120 may be configured by one of a capacitively coupled plasma (CCP) generating apparatus, an inductively coupled plasma (ICP) generating apparatus, and electron-cyclotron-resonance plasma (ECR plasma) generating apparatus and a helicon wave plasma (HWP) generating apparatus. Alternatively, various types of plasma generators including an alternating current (AC) plasma generator and a direct current (DC) plasma generator may be used.

The ion attraction device 130 is configured to attract the ions distributed in the plasma generated inside the processing container 100 onto the front surface W₁ of the wafer W on the stage 101. In an example, the ion attraction device 130 includes at least one electrode 131, a high frequency power supply 132, and a capacitor 133. The high frequency power supply 132 may also be used to generate plasma inside the processing container 100 as well as to attract the ions onto the front surface W₁ of the wafer W. Therefore, the high frequency power supply 132 supplies at least one of a source power or a bias power to the electrode 131.

The exhaust device 140 is connected to, for example, a gas exhaust opening 100e provided at a bottom portion of the processing container 100. The exhaust device 140 may include a pressure adjusting valve and a vacuum pump. An internal pressure of the processing container 100 is adjusted by the pressure adjusting valve. The vacuum pump may include a turbo molecular pump, a dry pump, or a combination thereof.

The surface modifying apparatus 30 is configured as described above. The above-described configuration is just an example, and the surface modifying apparatus 30 may have any configuration as long as it can modify the front surface W₁ of the wafer W.

The surface hydrophilizing apparatus 40 is configured to supply a processing liquid onto the front surface W₁ of the wafer W while rotating the wafer W held by, for example, a spin chuck. Then, the supplied processing liquid is spread on the front surface W₁ of the wafer W by a centrifugal force, and, thus, the front surface W₁ is hydrophilized.

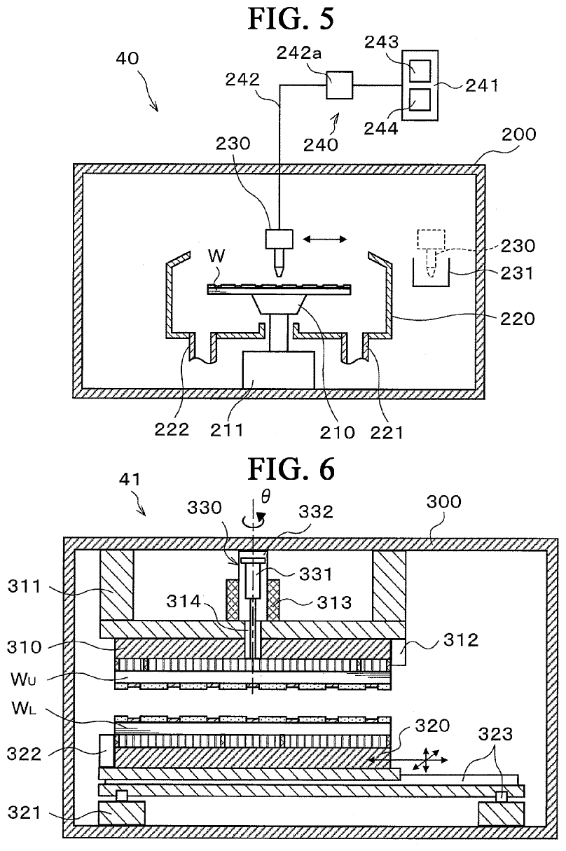

As shown in FIG. 5, the surface hydrophilizing apparatus 40 includes a processing container 200, a spin chuck 210, a cup 220, a discharge nozzle 230, and a liquid supply mechanism 240.

The processing container 200 has a hermetically sealable inside. A non-illustrated carry-in/out opening for the wafer W is formed at the processing container 200, and the carry-in/out opening is provided with a non-illustrated gate valve. The spin chuck 210 configured to hold the front surface W₁ of the wafer W facing upwards and rotate the wafer W around a vertical axis is placed at a central portion inside the processing container 200. The spin chuck 210 includes a driving mechanism 211 having, for example, a motor or the like. The driving mechanism 211 may be provided with an elevation driving source such as a cylinder or the like.

Around the spin chuck 210, the cup 220 is provided to receive and collect a liquid splashing or dropping from the wafer W. A drain pipe 221 that drains the collected liquid and an exhaust pipe 222 that exhausts the atmosphere inside the cup 220 are connected to a lower surface of the cup 220.

Above the spin chuck 210, the discharge nozzle 230 supported by a non-illustrated arm is provided. The discharge nozzle 230 can move from a stand-by section 231 provided outside the cup 220 to a position above the central portion of the wafer W inside the cup 220, and can also move above the wafer W in a diametrical direction of the wafer W. Further, a height of the discharge nozzle 230 can be adjusted with respect to the front surface W₁ of the wafer W by a non-illustrated elevation mechanism.

The discharge nozzle 230 is connected to the liquid supply mechanism 240 configured to supply the processing liquid to the front surface of the wafer W on the spin chuck 210. The liquid supply mechanism 240 includes a processing liquid source 241 configured to store the processing liquid therein and supply the processing liquid to the discharge nozzle 230, and a processing liquid supply line 242 that connects the processing liquid source 241 and the discharge nozzle 230.

An adjusting mechanism 242a including a regulator, a manometer, a flow rate detector, a valve and a filter is provided in the processing liquid supply line 242. The adjusting mechanism 242a can measure and adjust a pressure and/or a flow rate of the processing liquid flowing inside the processing liquid supply line 242, and can collect and remove particles in the processing liquid. The types, numbers and configurations of the regulator, the manometer, the flow rate detector, the valve and the filter are not particularly limited.

According to the present exemplary embodiment, a weak alkaline solution, for example, diluted ammonia water (dNH₄OH) is used in the surface hydrophilizing processing for the wafer W. Therefore, for example, ammonia water is stored in the processing liquid source 241 of the liquid supply mechanism 240.

Further, in the present exemplary embodiment, the liquid supply mechanism 240 is equipped with a hydrogen ion concentration (hereinafter, referred to as “pH”) adjusting device 243 and an oxidation reduction potential (hereinafter, referred to as “ORP”) adjusting device 244.

The pH adjusting device 243 is configured to adjust a pH of the processing liquid (ammonia water in the present exemplary embodiment) supplied to the front surface W₁ of the wafer W to a desired value by controlling, for example, a concentration of the processing liquid. Further, the configuration of the pH adjusting device 243 is not limited thereto, and the pH adjusting device 243 may have any configuration as long as it can adjust the pH of the processing liquid.

The ORP adjusting device 244 is configured to adjust an ORP of the processing liquid supplied to the front surface W₁ of the wafer W to a desired value by mixing a hydrogen gas or hydrogen water with the processing liquid and changing the amount of dissolved hydrogen in the processing liquid. Further, the configuration of the ORP adjusting device 244 is not limited thereto, and the ORP adjusting device 244 may have any configuration as long as it can adjust the ORP of the processing liquid.

The surface hydrophilizing apparatus 40 is configured as described above. The above-described configuration is just an example, and the surface hydrophilizing apparatus 40 may have any configuration as long as it can hydrophilize the front surface W₁ of the wafer W.

In the bonding apparatus 41, the front surface W_{U1} and the front surface W_{L1}, which are obtained by sequentially performing the surface modifying processing and the surface hydrophilizing processing on the upper wafer W_{U} and the lower wafer W_{L}, are bonded to each other.

As shown in FIG. 6, the bonding apparatus 41 includes a processing container 300, an upper chuck 310, a lower chuck 320, and a pressing device 330.

The processing container 300 has a hermetically sealable inside. A non-illustrated carry-in/out opening for the wafer W is formed at the processing container 300, and the carry-in/out opening is provided with a non-illustrated gate valve. The upper chuck 310 is placed at a ceiling portion of the processing container 300, and the lower chuck 320 is placed at a bottom portion of the processing container 300.

The upper chuck 310 is configured to attract and hold the rear surface W_{U2} of the upper wafer W_{U} on a lower surface thereof. The upper chuck 310 is supported by an upper chuck stage 311 provided on the upper chuck 310. The upper chuck stage 311 is equipped with an upper imaging device 312 configured to image the front surface W_{U1} of the lower wafer W_{L} held by the lower chuck 320. For example, a CCD camera is used as the upper imaging device 312.

The upper chuck 310 is also equipped with a rotary device 313. The rotary device 313 is configured to rotate the upper chuck stage 311 and the upper chuck 310 around a vertical axis (0-axis). Further, the rotary device 313 may be equipped with a non-illustrated measurement device (for example, a linear scale) configured to measure a position of the upper chuck 310 in a 0-axis direction.

The lower chuck 320 is configured to attract and hold the rear surface W_{L2} of the lower wafer W_{L} on an upper surface thereof. The lower chuck 320 is provided under the upper chuck 310 and configured to be arranged to face the upper chuck 310. That is, the upper wafer W_{U} held by the upper chuck 310 and the lower wafer W_{L} held by the lower chuck 320 are arranged to face each other. The lower chuck 320 is supported by a lower chuck stage 321 provided under the lower chuck 320. The lower chuck stage 321 is equipped with a lower imaging device 322 configured to image the front surface W_{U1} of the lower wafer W_{U} held by the upper chuck 310. For example, a CCD camera is used as the lower imaging device 322.

The lower chuck 320 is also equipped with a moving device 323. The moving device 323 is configured to move the lower chuck stage 321 and the lower chuck 320 in a horizontal direction. Further, the moving device 323 is configured to move the lower chuck 320 in a vertical direction. Furthermore, the moving device 323 may be equipped with a non-illustrated measurement device (for example, a laser interferometer system) configured to measure a position of the lower chuck 320 in the horizontal direction and a position of the lower chuck 320 in the vertical direction.

The pressing device 330 configured to press the central portion of the upper wafer W_{U} from the rear surface W_{U2} side is provided on an upper surface of the upper chuck 310. The pressing device 330 includes an actuator member 331 and a cylindrical member 332.

The actuator member 331 is movable up and down in the vertical direction through a through-hole 314 formed through the central portions of the upper chuck 310 and the upper chuck stage 311 in a thickness direction. The actuator member 331 is brought into contact with the central portion of the upper wafer W_{U} by air supplied from, for example, an electro-pneumatic regulator and can control a press load applied to the central portion of the upper wafer W_{U}.

The actuator member 331 is supported by the cylindrical member 332. The cylindrical member 332 moves the actuator member 331 in the vertical direction by a driver including, for example, a motor.

As described above, the pressing device 330 uses the actuator member 331 to control the press load and the cylindrical member 332 to control the movement of the actuator member 331. Further, the pressing device 330 may press and bring the central portion of the upper wafer W_{U} and the central portion of the lower wafer W_{L} into contact with each other when the upper wafer W_{U} and the lower wafer W_{L} are bonded to each other as described below.

Further, in an outer peripheral portion of the lower chuck 320, non-illustrated guide members are provided to suppress the upper wafer W_{U}, the lower wafer W_{L} or the combined wafer W_{T} from jumping out or sliding down from the lower chuck 320. The guide members are provided at a plurality of, for example, four, locations, in the outer peripheral portion of the lower chuck 320 at equal intervals.

Furthermore, the bonding apparatus 41 may be equipped with a non-illustrated inverting device to invert the front surface and the rear surface of the upper wafer W_{U} transferred to the bonding apparatus 41 and attracted and held by the upper chuck 310. The upper wafer W_{U} is transferred to the bonding apparatus 41 in a state where the front surface W_{U1}, on which the surface modifying processing and the surface hydrophilizing processing have been performed, faces upwards. Since the front surface and the rear surface of the upper wafer W_{U} is inverted by the inverting device, the rear surface W_{U2} can be held by the upper chuck 310 appropriately.

However, the arrangement of the inverting device is not limited thereto. A non-illustrated inverting device configured to invert the front surface and the rear surface of the upper wafer W_{U} may be provided independently at a certain position in the processing station 3 of the bonding system 1 instead of inside the bonding apparatus 41.

The bonding apparatus 41 is configured as described above. The above-described configuration is just an example, and the bonding apparatus 41 may have any configuration as long as it can bond the front surface W_{U1} of the upper wafer W_{U} with the front surface W_{U} of the lower wafer W_{L}.

The transition devices 50 and 51 are stacked in the third processing block G3. The transition devices 50 and 51 temporarily hold the upper wafers W_{U}, the lower wafers W_{L} and the combined wafers W_{T} to deliver the upper wafers W_{U}, the lower wafers W_{L} and the combined wafers W_{T} between the wafer transfer device 22 in the wafer transfer section 20 of the carry-in/out station 2 and a wafer transfer device 62 in a wafer transfer section 60 to be described later.

As shown in FIG. 2, the wafer transfer section 60 is provided in a region surrounded by the first processing block G1 to the third processing block G3 of the processing station 3. The wafer transfer section 60 is equipped with the wafer transfer device 62 that is movable on a transfer path 61 elongated in the X-axis direction and can transfer the upper wafers W_{U}, the lower wafers W_{L} or the combined wafers W_{T} between the surface modifying apparatus 30, the surface hydrophilizing apparatus 40, the bonding apparatus 41, and the transition devices 50 and 51.

The above-described bonding system 1 is equipped with a control device 70. The control device 70 is implemented by a computer including, for example, a CPU and a memory, and includes a program storage (not shown). The program storage stores therein a program for controlling a wafer processing in the bonding system 1. Further, the program may be recorded on a computer-readable recording medium H and installed from the recording medium H to the control device 70. Furthermore, the recording medium H may be temporary or non-temporary medium.

### <Bonding Method>

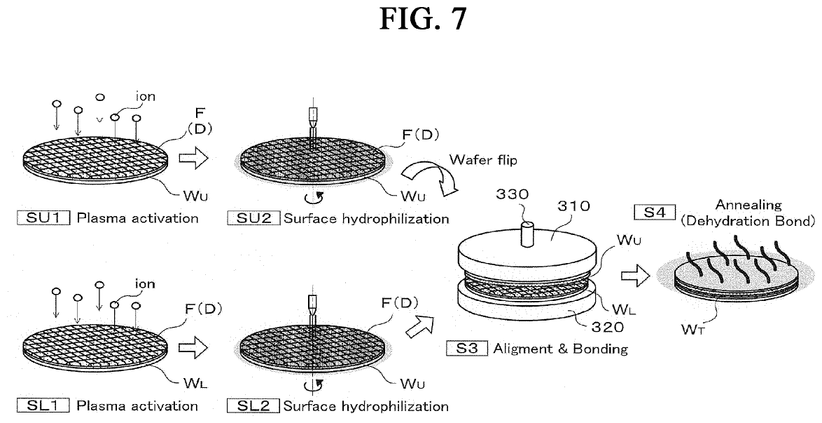

Hereinafter, a method of bonding the upper wafer W_{U} and the lower wafer W_{L} by using the bonding system 1 configured as described above will be described. FIG. 7 is an explanatory diagram illustrating main processes of a wafer processing performed in the bonding system 1.

First, a cassette C_{U} accommodating a plurality of upper wafers W_{U}, a cassette C_{L} accommodating a plurality of lower wafers W_{L} and an empty cassette C_{T} are placed on respective cassette placing plates 11 of the carry-in/out station 2. Then, an upper wafer W_{U} is taken out of the cassette C_{U} by the wafer transfer device 22 and transferred to the transition device 50 of the processing station 3.

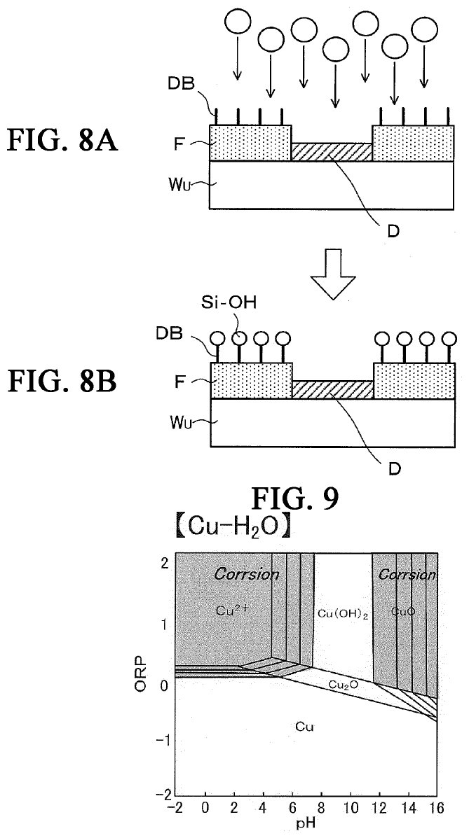

Subsequently, the upper wafer W_{U} is transferred into the surface modifying apparatus 30 by the wafer transfer device 62. In the surface modifying apparatus 30, an oxygen gas or a nitrogen gas as a processing gas is excited and formed into a plasma to be ionized in a desired depressurized atmosphere. The oxygen ions or nitrogen ions are radiated onto the front surface W_{U1} of the upper wafer W_{U}, and the front surface W_{U1} is plasma-processed. As a result, the front surface W_{U1} of the upper wafer W_{U} is modified (process SU1 in FIG. 7). In this surface modifying processing, the insulating film F exposed on the front surface W_{U1} of the wafer W is modified to form dangling bonds (DB) of silicon atoms, but the metal wiring D exposed on the front surface W_{U1} of the wafer W is not modified as shown in FIG. 8A.

Then, the upper wafer W_{U} is transferred into the surface hydrophilizing apparatus 40 by the wafer transfer device 62. In the surface hydrophilizing apparatus 40, the processing liquid is supplied onto the upper wafer W_{U} while rotating the upper wafer W_{U} held by the spin chuck. The supplied processing liquid is spread on the front surface W_{U1} of the upper wafer W_{U}, and hydroxyl groups (silanol groups) adhere to the front surface W_{U1} (dangling bonds (DB)) of the upper wafer W_{U} modified in the surface modifying apparatus 30. Thus, the front surface W_{U1} is hydrophilized. Therefore, in this surface hydrophilizing process, the hydroxyl groups adhere to the insulating film F exposed on the front surface W_{U1} of the wafer W, but the hydroxyl groups do not adhere to the metal wiring D as shown in FIG. 8B. Further, the front surface W_{U1} of the upper wafer W_{U} is cleaned by the processing liquid (process SU2 in FIG. 7). The surface hydrophilizing processing for the wafer W will be described in detail later.

Thereafter, the upper wafer W_{U} is transferred into the bonding apparatus 41 by the wafer transfer device 62. The front surface and the rear surface of the upper wafer W_{U} carried into the bonding apparatus 41 are inverted by the non-illustrated inverting device, and then, the rear surface W_{U2} of the upper wafer W_{U} is attracted and held by the upper chuck 310. Also, in this case, a position of the upper wafer W_{U} in the horizontal direction is adjusted by a non-illustrated position adjusting mechanism.

While the above-described processings are performed on the upper wafer W_{U}, processings are performed on the lower wafer W_{L}. First, the lower wafer W_{L} is taken out of the cassette C_{L} and transferred into the transition device 50 of the processing station 3 by the wafer transfer device 22.

Thereafter, the lower wafer W_{L} is transferred into the surface modifying apparatus 30 by the wafer transfer device 62, and the front surface W_{U1} of the lower wafer W₁ is modified (process SL1 in FIG. 7). Further, the modification of the front surface W_{L1} of the lower wafer W_{U} in the process SL1 is the same as the above-described process SU1.

Then, the lower wafer W_{L} is transferred into the surface hydrophilizing apparatus 40 by the wafer transfer device 62, and the front surface W_{U} of the lower wafer W_{L} is hydrophilized and cleaned (process SL2 in FIG. 7). Further, the hydrophilization and cleaning of the front surface W_{U} of the lower wafer W_{L} in the process SL2 is the same as the above-described process SU2. The surface hydrophilizing processing for the wafer W will be described in detail later.

Thereafter, the lower wafer W_{L} is transferred into the bonding apparatus 41 by the wafer transfer device 62. The rear surface W₁₂ of the lower wafer W_{L} carried into the bonding apparatus 41 is attracted and held by the lower chuck 320. Also, in this case, a position of the lower wafer W_{L} in the horizontal direction is adjusted by a non-illustrated position adjusting mechanism.

After the upper wafer W_{U} is attracted and held by the upper chuck 310 and the lower wafer W_{L} is attracted and held by the lower chuck 320, the upper wafer W_{U} held by the upper chuck 310 and the lower wafer W_{L} held by the lower chuck 320 are position-adjusted.

Specifically, predetermined reference points on the front surface W_{U1} of the lower wafer W_{L} held by the lower chuck 320 are imaged in sequence by the upper imaging device 312, and predetermined reference points on the front surface W_{U1} of the upper wafer W_{U} held by the upper chuck 310 are imaged in sequence by the lower imaging device 322. The obtained images are output to the control device 70. In the control device 70, the upper chuck 310 (the upper wafer W_{U}) is rotated by the rotary device 313 and the lower chuck 320 (the lower wafer W_{L}) is moved by the moving device 323 so that the reference points of the upper wafer W_{U} overlap the reference points of the lower wafer W_{L}, respectively, based on the images obtained by the upper imaging device 312 and the lower imaging device 322. In this way, the upper wafer W_{U} and the lower wafer W_{L} are position-adjusted and arranged at desired positions to face each other.

Then, the upper wafer W_{U} and the lower wafer W_{L} are bonded to each other (process S3 in FIG. 7).

Specifically, first, the actuator member 331 is lowered by the cylindrical member 332 to allow the actuator member 331 to come into contact with the central portion of the rear surface W_{U2} of the upper wafer W_{U}. Thereafter, the actuator member 331 is continuously lowered, and, thus, the central portion of the upper wafer W_{U} is pressed and lowered. Therefore, the central portion of the upper wafer W_{U} and the central portion of the lower wafer W_{L} are brought into contact with each other and pressed against each other. When the central portion of the upper wafer W_{U} and the central portion of the lower wafer W_{L} are brought into contact with each other and pressed against each other, bonding is started between the central portions. That is, since the front surface W_{U1} of the upper wafer W_{U} and the front surface W_{U} of the lower wafer W_{L} have been modified in processes SU1 and SL1, respectively, a van der Waals force (intermolecular force) is generated between the front surfaces W_{U1} and W_{L1}, and, thus, the front surfaces W_{U1} and W_{U} are bonded to each other. Also, since the front surface W_{U1} of the upper wafer W_{U} and the front surface W_{U} of the lower wafer W_{L} have been hydrophilized in the processes SU2 and SL2, respectively, the hydrophilic groups between the front surfaces W_{U1} and W_{L1} are hydrogen-bonded (which generates an intermolecular force). Thus, the front surfaces W_{U1} and W_{U} are strongly bonded to each other. Then, the bonding between the front surfaces W_{U1} and W_{U1} caused by the van der Waals force and the hydrogen bonding is diffused from the central portion toward an outer peripheral portion. When the entire front surface W_{U1} of the upper wafer W_{U} is bonded to the entire front surface W_{U} of the lower wafer W_{U}, the bonding processing of the upper wafer W_{U} and the lower wafer W_{L} is completed.

The combined wafer W_{T} obtained by bonding the upper wafer W_{U} and the lower wafer W_{L} is transferred to the transition device 51 by the wafer transfer device 62 and then transferred to the cassette C_{T} by the wafer transfer device 22 of the carry-in/out station 2. In this way, a series of operations of the bonding processing of the upper wafer W_{U} and the lower wafer W_{L} is completed.

Also, the combined wafer W_{T} obtained by bonding the upper wafer W_{U} and the lower wafer W₁ is heated (annealed) by a heating apparatus provided outside the bonding system 1 (process S4 in FIG. 7). In this heating processing, as the combined wafer W_{T} is heated, the metal wiring D formed on the front surface W₁ of the wafer W thermally expands along a wall surface of the recess (see FIG. 1), and, thus, a front surface of the metal wiring D formed on the upper wafer W_{U} and a front surface of the metal wiring D formed on the lower wafer W_{L} are strongly diffusion-bonded to be electrically connected to each other.

This heating processing may be performed outside the bonding system 1. However, the heating processing may be performed by a non-illustrated heating apparatus provided in the processing station 3 of the bonding system 1 after bonding of the upper wafer W_{U} and the lower wafer W_{L} in the bonding apparatus 41.

### <Surface Hydrophilizing Processing>

Hereinafter, the surface hydrophilizing processing according to the present exemplary embodiment will be described in detail.

As shown in a Pourbaix diagram shown in FIG. 9, a surface state of copper (Cu) serving as the metal wiring D is changed by a hydrogen ion concentration (a pH value) and an oxidation reduction potential (an ORP value) of the supplied processing liquid in the surface hydrophilizing processing.

Specifically, when the supplied processing liquid has strong reducing power (i.e., the ORP value is negative), the surface state (composition) of the metal wiring D is not changed. Meanwhile, when the supplied processing liquid has strong oxidizing power (i.e., the ORP value is positive), the surface state is further changed by the hydrogen ion concentration of the processing liquid.

That is, when the supplied processing liquid is acidic (with the pH value of 7 or less), the front surface of the metal wiring D is corroded and generates copper ions (Cu²⁺). Also, when the supplied processing liquid is strongly alkaline (with the pH value of, for example, 11 or more), coordinate covalent bond occurs between the metal wiring D and the processing liquid, and, thus, a complex having a high solubility is generated. Therefore, dissolution (corrosion) of the metal wiring D is highly likely to occur. In this case, the composition of the metal wiring D is changed by the corrosion of the metal wiring D, which suppresses bonding between the metal wirings D and degrades the quality, such as conductivity, of the metal wiring in a product wafer.

Meanwhile, when the supplied processing liquid is weakly alkaline, the composition of the metal wiring D is not changed (the metallic characteristics are maintained) and copper hydroxide or copper (I) oxide is generated on the front surface of the metal wiring D. The copper hydroxide or copper (I) oxide can promote the bonding between the metal wirings D of the upper wafer W_{U} and the lower wafer W_{L}.

In the bonding system 1 according to the present disclosure, the weak alkaline solution, for example, diluted ammonia water is used as the processing liquid to be supplied to the front surface W₁ of the wafer W in the surface hydrophilizing processing, and the pH value and the ORP value of the processing liquid to be supplied onto the wafer W is adjusted by the pH adjusting device 243 and the ORP adjusting device 244.

Specifically, in the surface hydrophilizing processing according to the present exemplary embodiment, the pH adjusting device 243 and the ORP adjusting device 244 are used to adjust the pH value and the ORP value of the processing liquid. Thus, a relationship between the pH value and the ORP value is set not to enter the corrosion region (hatched region) in the Pourbaix diagram shown in FIG. 9.

More specifically, the ORP adjusting device 244 adjusts the amount of dissolved hydrogen in the processing liquid to increase the reducing power of the processing liquid (to the ORP value of 0 or less), or the pH adjusting device 243 adjusts the concentration [ppm] of the processing liquid to set the hydrogen ion concentration (pH) of the processing liquid to about 7 to about 11. For example, in case of using ammonia water as the processing liquid, the hydrogen ion concentration (pH) is in the range of from 7 to 11 when the concentration thereof is from 1 ppm to 1000 ppm.

Accordingly, in the surface hydrophilizing apparatus 40, by adhering the hydroxyl groups (silanol groups) to the insulating film F, which has been surface-modified, on the front surface W₁ of the wafer W without changing the composition of the metal wirings D, the bonding between the metal wirings D in a non-illustrated heating apparatus can be promoted.

The thickness of copper hydroxide formed on the front surface of the metal wiring D by the supply of ammonia water, i.e., the reduced film amount of copper (Cu) serving as the metal wiring D (i.e., a recess amount), is changed by the pH value and the ORP value of the supplied ammonia water. Specifically, when the ammonia water has a high pH value (strong alkalinity) and a high ORP value (strong reducing power), the reduced film amount (i.e., the recess amount) is increased, whereas when the ammonia water has a low pH value (close to neutrality) and a low ORP value (weak reducing power), the reduced film amount (i.e., the recess amount) is decreased.

In view of this, the pH value and the ORP value are appropriately adjusted not to enter the corrosion region in the Pourbaix diagram, and, thus, the metal wiring D can be lowered (recessed) to a desired level. In this case, preferably, the surface hydrophilizing processing may include a process of controlling the pH value and the ORP value of the processing liquid to be constant at predetermined desired values, respectively, (a process of maintaining the pH value and the ORP value to desired values, respectively) at least until the recess amount of the metal wiring D is obtained to a desired level.

Therefore, according to the present disclosure, even when the metal wiring D formed on the front surface W₁ of the wafer W transferred to the bonding system 1 is not sufficiently recessed or the recess amount is not uniform in the plane of the wafer W, the recess amount of the metal wiring D is adjusted and the processing liquid is locally supplied by the surface hydrophilizing apparatus 40 prior to the bonding by the bonding apparatus 41. Thus, it is possible to suppress or correct the non-uniformity of the recess amount.

In the above-described exemplary embodiment, the recess amount of the metal wiring D is controlled by the pH value and the ORP value of the processing liquid to be supplied to the front surface W₁ of the wafer W. Also, the recess amount of the metal wiring D may be controlled more precisely by controlling a temperature of the processing liquid to be supplied, a supply time (a surface hydrophilizing processing time) or a supply amount of the processing liquid.

Specifically, the recess amount of the metal wiring D may be increased by increasing the temperature of the processing liquid and may be decreased by decreasing the temperature. For example, the temperature of the processing liquid to be supplied to the front surface W₁ of the wafer W may be controlled to a range of from 20° C. to 80° C. and preferably 60° C. or less.

Further, the recess amount of the metal wiring D may be increased by increasing the supply time or the supply amount of the processing liquid and may be decreased by decreasing the supply time or the supply amount.

In the above-described exemplary embodiment, the case where the metal wiring D formed on the front surface W₁ of the wafer W is copper (Cu) has been described, but the type of metal forming the metal wiring D is not limited thereto. Specifically, for example, cobalt (Co) may be used as the metal wiring D as described above. Even in this case, the bonding between the metal wirings D can be promoted by controlling at least the pH value and the ORP value of the processing liquid to be supplied, and the recess amount can be adjusted in the surface hydrophilizing apparatus 40 prior to the bonding.

Also, in the above-described exemplary embodiment, diluted ammonia water (dNH₄OH) is used as the processing liquid in the surface hydrophilizing processing. However, the type of the processing liquid is not limited thereto as long as the surface sate of the metal wiring D can be controlled by controlling the pH value and the ORP value of the processing liquid as described above.

For example, carbon dioxide water (CO₂ Water), which is the processing liquid conventionally used in the surface hydrophilizing processing, may also be used to obtain the same effect as in the technique according to the present disclosure by controlling the ORP value not to enter the corrosion region of the metal wiring D based on the Pourbaix diagram (not shown).

The exemplary embodiments disclosed herein are illustrative in all aspects and do not limit the present disclosure. Further, the above-described exemplary embodiments may be omitted, substituted, or changed in various forms without departing from the scope and spirit of the appended claims. For example, the constituent elements of the above-described exemplary embodiments may be combined in various ways. From any of these various combinations, functions and effects for the respective constituent elements are naturally obtained, and other functions and other effects obvious to those skilled in the art are also obtained from the description of the present specification.

Further, the effects described in the present specification are only explanatory or illustrative and are not limiting. That is, the technique according to the present disclosure may exhibit, together with or instead of the above-described effects, other effects obvious to those skilled in the art from the description of the present specification.

Furthermore, the following configuration examples are also included in the technical scope of the present disclosure.

(1) A bonding method of bonding substrates, a metal material being exposed on each of the substrates, the bonding method including:
modifying a surface of each of the substrates to be bonded with a plasma of a processing gas;
hydrophilizing the modified surface of each of the substrates; and
bonding the hydrophilized surfaces of the substrates,
wherein in the hydrophilizing of the modified surface,
a processing liquid is supplied to the surface of each of the substrates, and a recess amount of the metal material is controlled with the processing liquid.

(2) The bonding method as described in (1), wherein the recess amount is controlled by a hydrogen ion concentration of the processing liquid.

(3) The bonding method as described in (2), wherein the hydrogen ion concentration of the processing liquid is controlled in a range of from pH 7 to pH 11.

(4) The bonding method as described in (3), wherein ammonia water is used as the processing liquid.

(5) The bonding method as described in (4), wherein a concentration of the ammonia water is adjusted from 1 ppm to 1000 ppm.

(6) The bonding method as described in (2) or (3), further including maintaining the hydrogen ion concentration of the processing liquid to a predetermined constant pH value.

(7) The bonding method as described in any one of (1) to (6), wherein the recess amount is controlled by an oxidation reduction potential of the processing liquid.

(8) The bonding method as described in (7), wherein the oxidation reduction potential of the processing liquid is controlled to an ORP value of 0 or less.

(9) The bonding method as described in (7) or (8), further including maintaining the oxidation reduction potential of the processing liquid to a predetermined constant ORP value.

(10) The bonding method as described in any one of (1) to (9), wherein the recess amount is controlled by at least one of a temperature, a flow rate and a supply time of the processing liquid.

(11) The bonding method as described in (10), wherein the temperature of the processing liquid is controlled from 20° C. to 80° C.

(12) The bonding method as described in any one of (1) to (11), wherein the metal material is copper.

(13) The bonding method as described in any one of (1) to (12), further including heating a combined substrate formed by the bonding of the substrates.

(14) A bonding system configured to bond substrates, a metal material being exposed on each of the substrates, the bonding system including:
a surface modifying apparatus configured to modify a surface of each of the substrates to be bonded with a plasma of a processing gas;
a surface hydrophilizing apparatus configured to hydrophilize the modified surface of each of the substrates;
a bonding apparatus configured to bond the hydrophilized surfaces of the substrates; and
a control device,
wherein the control device performs a control of supplying a processing liquid to the surface of each of the substrates in the surface hydrophilizing apparatus and adjusting a recess amount of the metal material with the processing liquid.

(15) The bonding system as described in (14), wherein the surface hydrophilizing apparatus is equipped with a pH adjusting device configured to adjust a hydrogen ion concentration of the processing liquid.

(16) The bonding system as described in (14) or (15), wherein the surface hydrophilizing apparatus is equipped with an ORP adjusting device configured to adjust an oxidation reduction potential of the processing liquid.

(17) The bonding system as described in any one of (14) to (16), wherein the processing liquid is ammonia water.

(18) The bonding system as described in any one of (14) to (17), wherein the metal material is copper.

(19) The bonding system as described in any one of (14) to (18), further including a heating apparatus configured to heat a combined substrate formed in the bonding apparatus.

According to the present disclosure, it is possible to improve the bonding quality of the substrates bonded to form the combined substrate.

From the foregoing, it will be appreciated that various exemplary embodiments of the present disclosure have been described herein for purposes of illustration and various changes can be made without departing from the scope and spirit of the present disclosure. Accordingly, various exemplary embodiments described herein are not intended to be limiting, and the true scope and spirit are indicated by the following claims.

We claim:

1. A bonding method of bonding substrates, a metal material being exposed on each of the substrates, the bonding method comprising:
modifying a surface of each of the substrates to be bonded with a plasma of a processing gas;
hydrophilizing the modified surface of each of the substrates; and
bonding the hydrophilized surfaces of the substrates,
wherein in the hydrophilizing of the modified surface,
a processing liquid is supplied to the surface of each of the substrates, and a recess amount of the metal material is controlled with the processing liquid.

2. The bonding method of claim 1,
wherein the recess amount is controlled by a hydrogen ion concentration of the processing liquid.

3. The bonding method of claim 2,
wherein the hydrogen ion concentration of the processing liquid is controlled in a range of from pH 7 to pH 11.

4. The bonding method of claim 3,
wherein ammonia water is used as the processing liquid.

5. The bonding method of claim 4,
wherein a concentration of the ammonia water is adjusted from 1 ppm to 1000 ppm.

6. The bonding method of claim 2, further comprising:
maintaining the hydrogen ion concentration of the processing liquid to a predetermined constant pH value.

7. The bonding method of claim 1,
wherein the recess amount is controlled by an oxidation reduction potential of the processing liquid.

8. The bonding method of claim 7,
wherein the oxidation reduction potential of the processing liquid is controlled to an ORP value of 0 or less.

9. The bonding method of claim 7, further comprising:
maintaining the oxidation reduction potential of the processing liquid to a predetermined constant ORP value.

10. The bonding method of claim 1,
wherein the recess amount is controlled by at least one of a temperature, a flow rate and a supply time of the processing liquid.

11. The bonding method of claim 10,
wherein the temperature of the processing liquid is controlled from 20° C. to 80° C.

12. The bonding method of claim 1,
wherein the metal material is copper.

13. The bonding method of claim 1, further comprising:
heating a combined substrate formed by the bonding of the substrates.

14. A bonding system configured to bond substrates, a metal material being exposed on each of the substrates, the bonding system comprising:
a surface modifying apparatus configured to modify a surface of each of the substrates to be bonded with a plasma of a processing gas;
a surface hydrophilizing apparatus configured to hydrophilize the modified surface of each of the substrates;
a bonding apparatus configured to bond the hydrophilized surfaces of the substrates; and
a control device,
wherein the control device performs a control of supplying a processing liquid to the surface of each of the substrates in the surface hydrophilizing apparatus and adjusting a recess amount of the metal material with the processing liquid.

15. The bonding system of claim 14,
wherein the surface hydrophilizing apparatus is equipped with a pH adjusting device configured to adjust a hydrogen ion concentration of the processing liquid.

16. The bonding system of claim 14,
wherein the surface hydrophilizing apparatus is equipped with an ORP adjusting device configured to adjust an oxidation reduction potential of the processing liquid.

17. The bonding system of claim 14,
wherein the processing liquid is ammonia water.

18. The bonding system of claim 14,
wherein the metal material is copper.

19. The bonding system of claim 14, further comprising:
a heating apparatus configured to heat a combined substrate formed in the bonding apparatus.
